(19) United States
(12) Patent Application Publication
(10) Pub. No.: US 2026/0282814 A1
(43) Pub. Date: Sep. 17, 2026

(54) SYSTEM AND METHOD FOR SEMICONDUCTOR CLEANING OPERATION

(71) Applicant: TAIWAN SEMICONDUCTOR MANUFACTURING COMPANY LTD., HSINCHU (TW)

(72) Inventor: KUAN-CHUNG CHEN, HSINCHU CITY (TW)

(21) Appl. No.: 19/080,980

(22) Filed: Mar. 17, 2025

(51) Int. Cl. H10P 72/00

(52) U.S. Cl. CPC H10P 72/0612; H10P 72/0616

(57) ABSTRACT

A system and a method of performing a semiconductor cleaning operation are provided. The method includes: receiving a workpiece including a material layer; receiving at least one input parameter associated with a cleaning operation for the material layer; determining a predicted cleaning configuration for the cleaning operation based on a prediction model and the at least one input parameter; performing the cleaning operation based on the predicted cleaning configuration; and performing a defect inspection operation on the material layer.

### BACKGROUND

During a semiconductor fabrication process, the semiconductor wafers may undergo numerous processing operations to form circuit features thereon. After the processing operations, some unintended particles or material residues may be left on the surface of the semiconductor wafers. These particles or residues left on the wafer's surface can cause problems on the later-performed operations and adversely affect the production yield and performance of the fabricated semiconductor devices. Various kinds of cleaning operations have been introduced to clean the surface of the semiconductor wafers between two processing operations in order to ensure the surface cleanliness of the semiconductor wafer can meet the requirement.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a block diagram of a semiconductor processing system, in accordance with some embodiments of the present disclosure.

FIG. 2 shows a schematic diagram of a defect inspection operation, in accordance with some embodiments of the present disclosure.

FIG. 3 shows an image generated by a defect inspection assembly, in accordance with some embodiments of the present disclosure.

FIG. 4A shows a schematic diagram of a training phase of a cleaning configuration prediction framework, in accordance with some embodiments of the present disclosure.

FIG. 4B shows a schematic diagram of a prediction phase of a cleaning configuration prediction framework, in accordance with some embodiments of the present disclosure.

FIG. 4C shows a schematic diagram of a training phase of a cleaning configuration prediction framework, in accordance with some embodiments of the present disclosure.

FIG. 4D shows a schematic diagram of a prediction phase of a cleaning configuration prediction framework, in accordance with some embodiments of the present disclosure.

FIG. 5A shows a schematic diagram of a prediction model, in accordance with some embodiments of the present disclosure.

FIG. 5B shows a schematic diagram of a prediction model, in accordance with some embodiments of the present disclosure.

FIG. 6 shows a flowchart of a wet cleaning method, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as "first," "second" and "third" describe various elements, components, regions, layers and/or sections, these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Wafer cleaning is a semiconductor processing operation widely adopted in modern semiconductor fabrication procedures. The wafer cleaning operation is used to remove contaminants, e.g., material residues or foreign particles found during the semiconductor fabrication process. According to some embodiments, after a semiconductor processing operation, e.g., a photolithography operation, an etching operation, a deposition operation, an ion implantation operation, or the like, is performed on the wafer, some contaminants may be left on the surface of the wafer. The contaminants may leave the wafer surface defective, and cause reliability issues and quality degradation in the subsequent semiconductor processes. Wafer cleaning is thus introduced to treat the wafer surface by removing the unwanted contaminants from the wafer surface while keeping the characteristics of the wafer surface unchanged or undamaged.

The wafer cleaning process can be performed through a dry cleaning method or a wet cleaning method. The dry and wet cleaning methods may be used depending on different cleaning scenarios and requirements. When the wet cleaning method is used, one or more workpieces, e.g., a semiconductor wafer, is transferred to a wet cleaning tool and subjected to one or more wet cleaning solutions. One or more nozzles arranged around the workpiece can flow cleaning solutions (e.g., a chemical solution, deionized water, etc.) onto the semiconductor wafer surface to remove unwanted contaminants. The cleaning solution would interact with the residues or contaminants with an interaction of a physical or a chemical manner, or both. After the wet cleaning operation, the semiconductor wafer can be dried and released from the wet cleaning tool. The used cleaning solution may be drained and recycled to a chemical container, e.g., a tank, containing the cleaning solution for reuse in another cleaning operation for the purpose of saving cost.

As the cleaning solution has been used multiple times in different wet cleaning operation rounds for different semiconductor wafers, the purity and cleaning capability of the cleaning solution would continue to decline. Since the performance of the wet cleaning operation is closely related to the performance of the cleaning solution, it is important to monitor the quality of the cleaning solution and examine whether the reused cleaning solution can still be reused in subsequent cleaning operation rounds. One of the cleaning solution management approaches is to replace the cleaning solution on a basis of a fixed number of processed semiconductor wafers or a fixed number of cleaning operations. However, such fixed-number-based method is unable to adapt to different cleaning scenarios, e.g., different contamination levels across different semiconductor wafers in the same or different batches. The source of contamination level difference across different semiconductor wafers may involve a pyramid of factors, such as the processing type of a previous operation before the wet cleaning operation, the circuit pattern type on the semiconductor wafer, etc., that is difficult to track and predict. Thus, an effective and dynamic cleaning solution management method may not be achievable through trial-and-error experiments.

Embodiments of the present disclosure disclose a prediction model-based management framework for the cleaning solution or the whole cleaning configuration of the wet cleaning operation for improving efficiency of the wet cleaning operation while optimizing the reuse (or recycle) number of the cleaning solution. The prediction model may be expressed in a form of an artificial neural network or other suitable types of artificial intelligence, and is trained using the sensing data collected from the wet cleaning tools and/or environment-related data from the clean room where the cleaning tool resides. The sensing data may include various kinds of data measured by different sensors or accessed as historic data from a database for aiding in predicting the cleaning performance of the upcoming cleaning operation using the current cleaning solution and other cleaning configurations. The prediction model can help determine whether to replace the cleaning solution with a new cleaning solution or reuse the current cleaning solution. The prediction process can be performed dynamically on the basis of every semiconductor wafer or a batch of semiconductor wafers. Thus, the cleaning performance of the wet cleaning operation can be increased to the level of each and every semiconductor wafer being cleaned without sacrificing the use efficiency of the cleaning solution, and the processing time and cost of the wet cleaning operation can be enhanced.

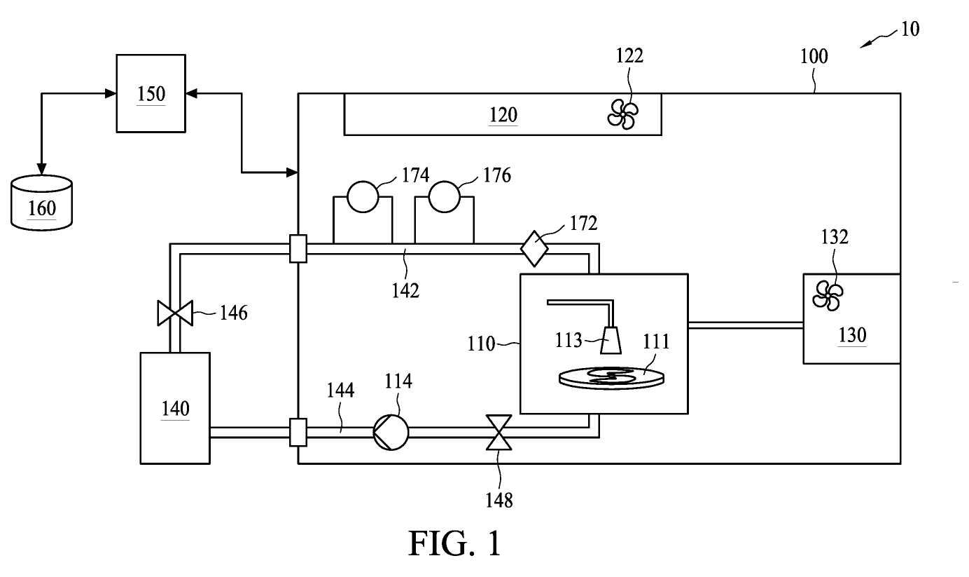

FIG. 1 is a block diagram of a semiconductor processing system 10, in accordance with some embodiments of the present disclosure. According to some embodiments, the semiconductor processing system 10 includes a clean room 100. The clean room 100 may include a semiconductor processing tool 110 and a chemical container 140. Although FIG. 1 only illustrates one semiconductor processing tool 110, other numbers of the semiconductor processing tool 110 are also within the contemplated scope of the present disclosure. According to some embodiments, the clean room 100 may include more tools or components although these tools and components are not shown in FIG. 1.

According to some embodiments, the semiconductor processing tool 110 includes a wet cleaning tool, e.g., in a form of a station or a chamber to accommodate a workpiece 111 within, configured to perform a wet cleaning operation. The semiconductor processing tool 110 may include a wafer holder (not separately shown) arranged in the chamber of statin and configured to support and hold the workpiece 111, such as semiconductor wafer. The workpiece 111 can be transferred to the wafer holder by a robot. According to some embodiments, the semiconductor processing tool 110 further includes a spin base (not separately shown) coupled to the wafer holder. Further, the semiconductor processing tool 110 includes one or more nozzles 113 around the workpiece 111 and configured to dispense one or more cleaning solutions to the surface of the workpiece 111.

During a wet cleaning operation, the workpiece 111 is spun by the spin base about a central axis perpendicular to the surface of the workpiece 111 while the cleaning solution is dispensed to the surface of the workpiece 111 via the nozzles 113. The flow rate of the cleaning solution and the spinning rate of the spin base can be managed such that the cleaning solution can be distributed on the surface of the workpiece 111 with a suitable and uniform amount. Although FIG. 1 only illustrates a nozzle 113 arranged above the workpiece 111 for cleaning the upper surface thereof, multiple nozzles 113 are possible, and the semiconductor processing tool 110 can include one or more nozzles arranged below the workpiece 111 for cleaning the lower surface thereof. Moreover, the semiconductor processing tool 110 may include different nozzles configured to dispense different kinds of cleaning solutions to remove the residues or particles of different materials.

According to some embodiments, the clean room 100 further includes a pipeline network configured to transport the cleaning solution between the chemical container 140 and the semiconductor processing tool 110. For example, the semiconductor processing system 10 includes a representative first pipe 142 and a representative second pipe 144 that connect the chemical container 140 to the semiconductor processing tool 110. The first pipe 142 is used to deliver the cleaning solution from the chemical container 140 to the semiconductor processing tool 110 for the cleaning operation, while the second pipe 144 is used to return the cleaning solution from the semiconductor processing tool 110 back to the chemical container 140. Together, the first pipe 142 and the second pipe 144 form a recycling pipeline that circulates and reuses the cleaning solution for multiple rounds of cleaning operations.

According to some embodiments, the semiconductor processing system 10 further includes valves on the pipeline network to switch on and off the pipes of the pipeline network for managing transport of the cleaning solution. For example, the semiconductor processing system 10 includes a first valve 146 and a second valve arranged on the first pipe 142 and the second pipe 144, respectively, and configured to control opening and closing of the respective first pipe 142 and second pipe 144. According to some embodiments, the semiconductor processing system 10 also includes a pump 114 arranged on the second pipe 144 (may also be installed in other suitable locations of the pipeline network) and configured to pump the sprayed cleaning solution back to the chemical container 140 via the second pipe 144. According to some embodiments, a filter 172 is arranged on the first pipe 142 and configured to filter the cleaned materials or particles carried along with the cleaning solution flowing through the first pipe 142 to thereby increase the cleanliness and the number of recycles of the cleaning solution.

According to some embodiments, the semiconductor processing system 10 further includes a fan filter unit (FFU) 120 and an exhaust unit 130. The FFU 120 and the exhaust unit 130 together construct an air cleaning unit for controlling the air quality of the semiconductor processing system 10 and maintaining the particle count under a predetermined specification. The particles, such as the particulate matters, flowing in the free space of the semiconductor processing system 10 may attach to the surface of the workpiece 111 during the wet cleaning operation, thereby adversely affecting the performance of the wet cleaning operation. As such, according to some embodiments, operational parameters of the FFU 120 and the exhaust unit 130 are to be adaptively tuned during the wet cleaning operation for maintaining the particle count in the free space of the semiconductor processing system 10. For example, a fan 122 of the FFU 120 and a fan 132 of the exhaust unit 130 play an important role in filtering the particles in the air and exhausting a particle-containing gas generated during the wet cleaning operation. Thus, operational parameters, such as the rotational speeds or air flow rates of the fans 122 and 132 or an exhaust pressure of the fan 132 are to be sensed and adjusted based on the requirement of the wet cleaning operation.

According to some embodiments, the semiconductor processing system 10 further includes a plurality of sensors for collecting sensing data related to the performance of the wet cleaning operation. For example, a viscosity sensor 174 is arranged on the first pipe 142 and configured to sense the viscosity of the cleaning solution in real time. The viscous property of the cleaning solution may result from the materials, e.g., polymers, removed from the workpiece 111 during the wet cleaning operation, and the viscosity value of the cleaning solution may be inversely proportional to the usefulness of the cleaning solution. A viscosity value of substantially zero of a new, unused cleaning solution may serve as a baseline viscosity value. According to some embodiments, the more amount the removed residues or particles is dissolved or carried away within the cleaning solution, the higher value the viscosity of the cleaning solution will reach.

Moreover, according to some embodiments, a concentration sensor 176 is arranged on the first pipe 142 and configured to sense the concentration value of the chemicals or water in the cleaning solution in real time. The concentration of the chemicals in the cleaning solution should be kept within a suitable range, e.g., the concentration value is high enough to provide sufficient chemical reaction capability with the contaminants while also lower than a threshold to prevent potential risks of damaging the surface of the workpiece. Thus, the concentration value of the chemicals in the cleaning solution may be inversely proportional to the usefulness of the cleaning solution. A concentration value of a new, unused cleaning solution may serve as a baseline concentration value. According to some embodiments, the increase (decrease) of the chemical concentration lead to decrease (increase) of the concentration of water in the cleaning solution. Therefore, the water concentration is used as an alternative index of the concentration value of the cleaning solution.

The viscosity value and the concentration value of the cleaning solution are only two examples of the prediction parameters for the performance of the wet cleaning operation. More examples of the prediction parameters and how their instant values in the current cleaning operation are leveraged by a prediction model to in predict the performance of the next cleaning operation are provided in greater detail later.

The semiconductor processing system 10 may further include an analyzer 150 coupled to the clean room 100, and a database 160 coupled to the analyzer 150. The analyzer 150 may be electrically connected to the sensors of the semiconductor processing system 10 to access the sensing data in real time to receive (and optionally convert) these sensing data into corresponding prediction parameters. According to some embodiments, the semiconductor processing system 10 also includes a database 160 storing historic data of the wet cleaning operation. The analyzer 150 may be electrically connected to the database 160 to receive sensing data from, or transmit sensing data to, the database 160. The analyzer 150 may also update the database 160 by providing the most updated sensing data to the database 160.

According to some embodiments, the analyzer 150 includes a processor, a memory, an input/output (I/O) unit, a storage, etc. The processor may be configured to receive sensing data from the sensors. The processor may also be configured to execute instructions to execute the prediction model, and provide a predicted outcome for updating the cleaning configuration of each wet cleaning operation. Moreover, the processor may be configured to transmit action commands derived from the predicted outcome to the controllers of each components of the semiconductor processing system 10 for conducting the wet cleaning operation according to the updated cleaning configuration. According to some embodiments, the processor is configured to execute the prediction model in real time before each cleaning operation is performed for providing real-time update to the cleaning configuration. According to some embodiments, the processor is configured to store the received sensing data in the storage or transmit the same to the database 160, e.g., through the I/O unit, the memory, for updating the database 160.

The processor can be implemented or performed with a general purpose processor, e.g., a central processing unit (CPU), a graphic processing unit (GPU), a digital signal processor (DSP), an application specific integrated circuit (ASIC), a field programmable gate array (FPGA) or other programmable logic device, discrete gate or transistor logic, discrete hardware components, microcontroller, microprocessor, or any combination thereof designed to perform the functions described herein. A general-purpose processor can be a microprocessor, but in an alternative implementation, the processor can be any controller or microcontroller. The processor can also be implemented as a combination of computing devices, for example, a combination of a DSP and a microprocessor, a plurality of microprocessors, one or more microprocessors in conjunction with a DSP core, or any other such configuration.

The I/O unit may include an input device and an output device configured for enabling user interaction with the semiconductor processing system 10. In some embodiments, the input unit includes, for example, a keyboard, a mouse, a microphone and other devices for receiving the operator’s instructions. The output unit includes, for example, a display, a printer, a speaker, and other devices for displaying the results responsive to the operator’s instructions.

The storage may configured for storing program instructions and data accessed by the program instructions. In some embodiments, the storage includes a non-transitory computer readable storage medium, for example, a flash memory, a magnetic disk, an optical disk or the like.

The memory may be configured to store program instructions to be executed by the processor and data accessed by the program instructions. In some embodiments, the memory includes any combination of a random access memory (RAM), some other volatile storage device, a read only memory (ROM), and some other non-volatile storage device.

According to some embodiments, a wet cleaning operation can be formed of multiple cleaning steps, in which the cleaning solutions are different in each step. According to some embodiments, the cleaning solution can be an acidic chemical, an alkaline chemical, deionized water, and/or reactive oxygen solution. Typical cleaning solutions may include a hydrochloric acid/hydrogen peroxide/deionized (DI) water (HPM) solution, a sulfuric acid/hydrogen peroxide/DI water (SPM) solution, a hydrofluoric acid/DI water (DHF) solution, an ozone solution (ozone diluted in water), or combinations thereof. Typical alkaline cleaning solutions include tetramethylammonium hydroxide (TMAH), ammonia, or combinations thereof. The cleaning solution may be dispensed on the workpiece 111 in sequence in different stages of a wet cleaning operation. For example, an exemplary wet cleaning operation can include a DHF step and an HPM step with another cleaning step in between. According to some other embodiments, the wet cleaning operation may refer to a single wet cleaning step with a single cleaning solution.

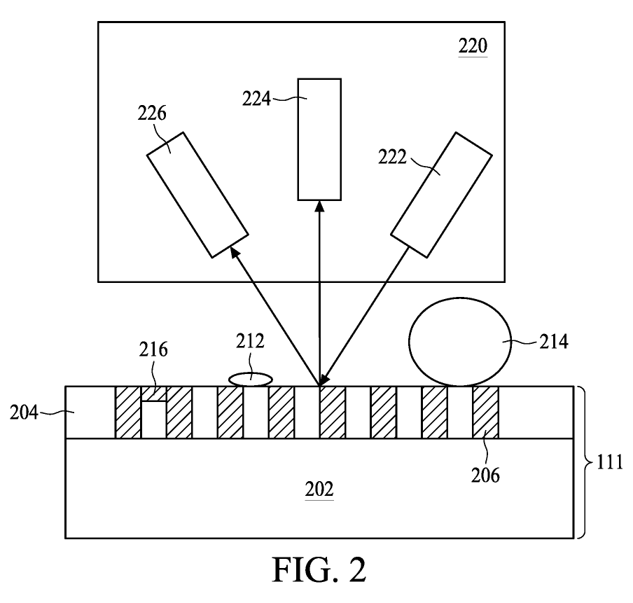

FIG. 2 shows a schematic diagram of a defect inspection operation, in accordance with some embodiments of the present disclosure. According to some embodiments, the workpiece 111 shown in FIG. 1 includes a substrate 202 and a material layer 204 disposed over the substrate 202 as illustrated in FIG. 2. The material layer 204 may be subject to a semiconductor processing operation, e.g., a photolithography operation, an etching operation, a deposition operation, an ion implantation operation, or other suitable operations. As a result, the material layer 204 may include one or more features 206, which may represent a conductive feature, a dielectric feature, a semiconductor feature, or the like. According to some embodiments, the surface of the material layer 204 include a trench, a recess, a mesa or other types of non-flat topography after being subjected to one or more semiconductor processing operations. Subsequently, a wet cleaning operation is performed to clean the surface of the material layer 204. According to some embodiments, a cleaning step using deionized water is performed to clean the surface of the workpiece 111 after the wet cleaning operation. The deionized water may be drained without being recycled.

After the wet cleaning operation, a defect inspection assembly 220 is used for performing a defect inspection operation on the material layer 204 of the workpiece 111. The material layer 204 may be partitioned into a plurality of inspection areas, and the inspection areas of the material layer 204 are scanned by the defect inspection assembly 220 in a predetermined sequence. As an example defect inspection device, the defect inspection assembly 220 includes an optical source 222, a first photo receiver 224 and a second photo receiver 226, and is configured to perform optical inspection of defects. The optical source 222 may include a laser diode configured to emit an inspection light beam onto the surface of the material layer 204. The first photo receiver 224 and the second photo receiver 226 may each include a photodiode configured to receive the scattered light and the reflected light, respectively, emitted from the surface of the material layer 204. FIG. 2 merely illustrates the optical source 222, the first photo receiver 224 and the second photo receiver 226 of the defect inspection assembly 220. Other components, such as the image analyzer, the polarizer, the optional half-wave plate, the focusing lens, the collecting lens, the collimating lens, the prism, and the like, may be omitted from FIG. 2 for brevity.

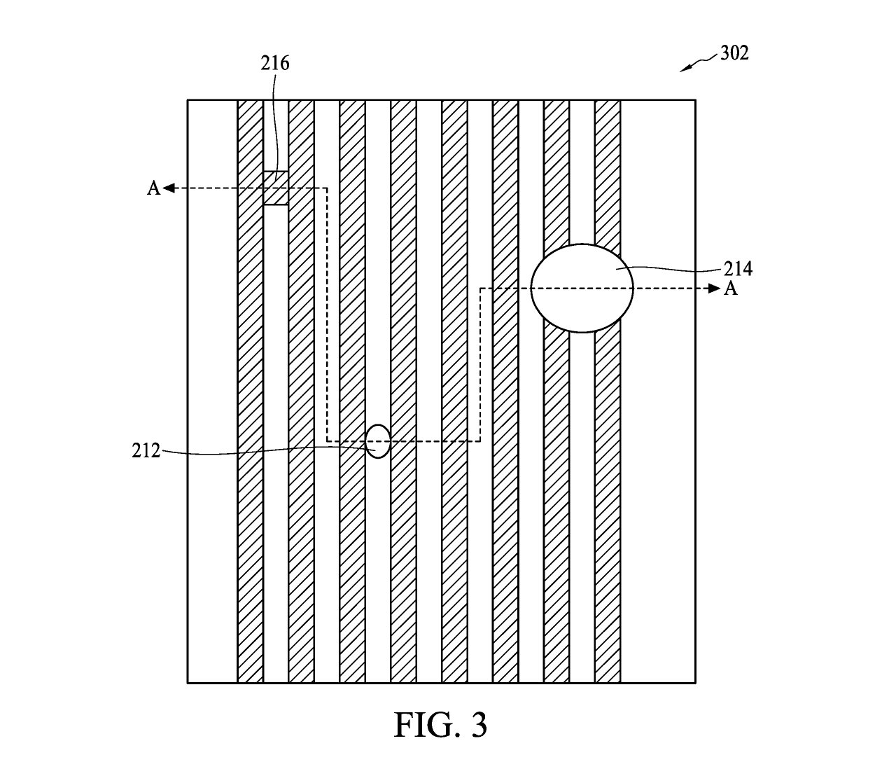

An image of the surface of the material layer 204 is generated according to the light received by the first photo receiver 224 and the second photo receiver 226. FIG. 3 shows an image 302 of a top view of the material layer 204 generated by the defect inspection assembly 220 during a defect inspection operation, in accordance with some embodiments of the present disclosure. The cross-sectional view of the workpiece 111 shown in FIG. 2 is taken from the sectional line AA shown in the image 302 of FIG. 3. As illustrated in FIGS. 2 and 3, three representative defects 212, 214 and 216 are found on the surface of the material layer 204. The defects 212, 214 and 216 may be detected by a defect inspection operation after a wet cleaning operation.

According to some embodiments, the defect 212 represents a first defect type, which is in a form of a material residue and is not removed successfully by the wet cleaning operation. The first defect type may further include a ball type defect and a non-ball type defect, in which the ball type defect and non-ball type defects may occur in different situations. According to some embodiments, the defect 214 represents a second defect type, which is in a form of a foreign particle and is left on the surface of the material layer 204 during or after the wet cleaning operation. According to some embodiments, the defect 216 represents a third defect type, which is caused by some previous processing operation and cannot be dealt with by the wet cleaning operation. The defects of the first defect type and the second defect type may be the targeted defects of interest to the proposed cleaning framework. Although defects of the third defect type are detected after the wet cleaning operation, they are not relevant to the performance of the wet cleaning operation, and thus are not attributed to the outcome of an ineffective wet cleaning operation. Therefore, according to some embodiments, when the image 302 is transmitted to the analyzer 150 of the semiconductor processing system 10, followed by defect inspection and classification, the defect 216 of the third defect type should be excluded as a defect during the process of defect counting and classification.

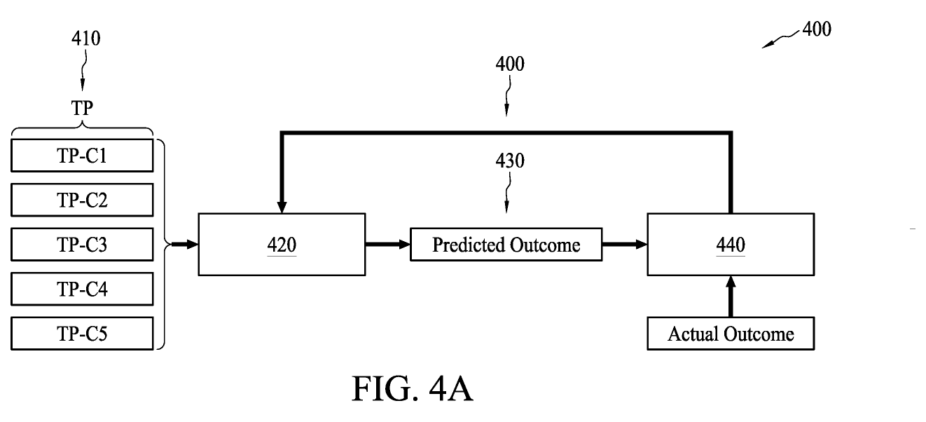

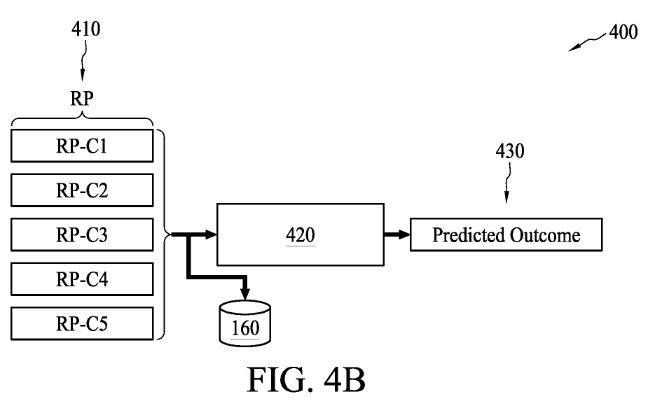

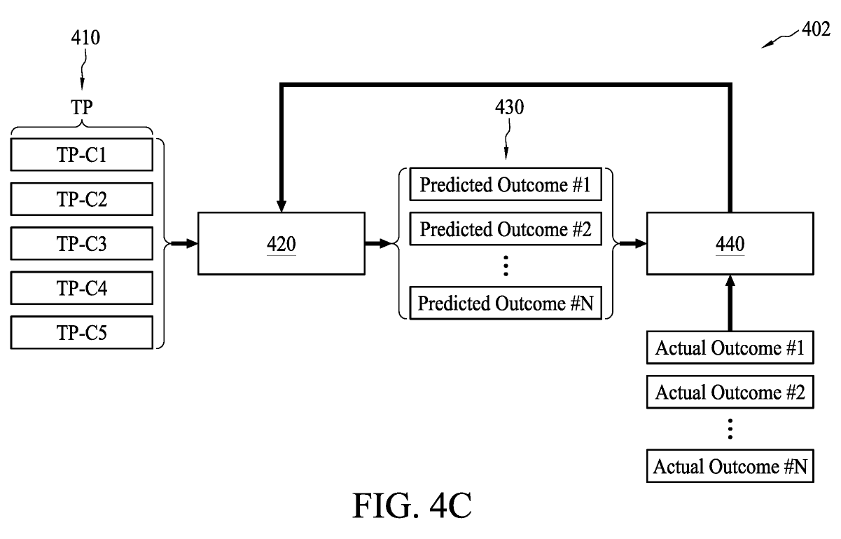

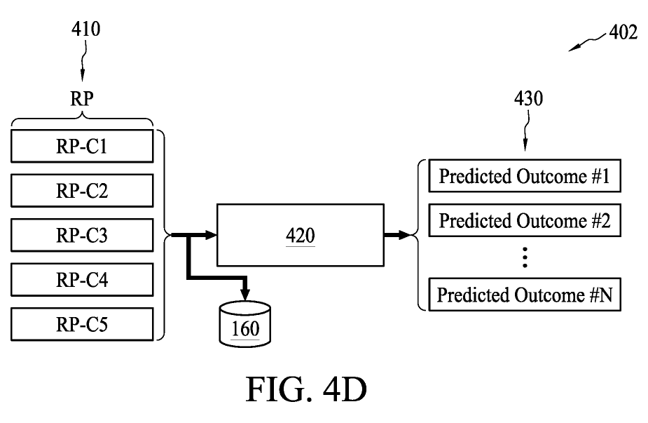

FIG. 4A shows a schematic diagram of a training phase of a cleaning configuration prediction framework 400, in accordance with some embodiments of the present disclosure. The cleaning configuration prediction framework 400 includes an input stage 410, a prediction model 420, an output stage 430, and an error function stage 440. The cleaning configuration prediction framework 400 is used to help provide an AI (artificial intelligence)-aided cleaning configuration at the output stage 430 for the upcoming cleaning operation based on the real-time input parameters RP at the input stage 410 in a prediction phase. Before the cleaning configuration prediction framework 400 can work well in the prediction phase, the prediction model 420 should be trained using training data (from the training input parameters TP) during the training phase to learn the relevance between the parameters of the input stage 410 and the predicted outcome at the output stage 430. According to some embodiments, the training input parameters TP of the input stage 410 for a past certain cleaning operation and the corresponding image are labeled to form a certain data group of the training input parameters TP. According to some embodiments, an image 302 for a first cleaning operation may be used as part of the input parameters for predicting a cleaning configuration for a second cleaning operation subsequent to the first cleaning operation.

A large number of data groups of the training input parameters TP are collected and used to train the prediction model 420 during the training phase such that the model parameters of the prediction model 420 are tuned to learn the relationship between the input stage 410 and the output stage 430 before it can provide a real-time predicted outcome based on real-time input parameters RP. According to some embodiments, the output stage 430 includes a single predicted outcome value, e.g., a decision of whether the cleaning solution in the chemical container 140 should be replaced with a new cleaning solution. The predicted outcome is then compared with the actual outcome collected from previous cleaning operations to generate a training error using an error function defined in the error function stage 440. The training error is feedback to the prediction model 420 to tune the model parameters, e.g., through a local minimum searching algorithm such as the gradient decent method. According to some embodiments, the error function, also referred to as a loss function, of the error function stage 440 is represented as a specific formula, such as a mean square error (MSE) function, a mean absolute error (MAE) function, a root mean square error (RMSE) function, binary crossentropy, categorical crossentropy, sparse categorical crossentropy, or the like.

According to some embodiments, the data groups of the training data are fed into the input stage of the prediction model 420 by iterations to generate the corresponding training error. As the training process proceeds with iterations, the training error would tend to decrease and converge. The training phase would be determined as attaining the converged state if the training error fluctuates around a value which falls below a predetermined threshold, which means the model parameters of the prediction model 420 have captured the relationship between the input stage 410 and the output stage 430. Afterwards, during a prediction phase, real-time input parameters RP of the input stage 410 are collected and provided to the prediction model 420, and the prediction model 420 can provide a reliable predicted outcome in the output stage 430 for the upcoming cleaning operation.

According to some embodiments, the training input parameters TP of the input stage 410 are classified into various categories. The training input parameters TP of the same category may have more similar characteristics and effects on the performance of the cleaning operation, and have more interdependency in the prediction model 420 than the training input parameters TP in other categories. According to some embodiments, one parameter of the input stage 410 is shared by two or more categories. The training input parameters TP may be classified into a first category C1, a second category C2, a third category C3, a fourth category C4 and a fifth category C5.

According to some embodiments, the training input parameters P-C1 in the first category C1 may reflect a current cleanliness of the semiconductor processing system 10. The training input parameters P-C1 may at least include one or more of a viscosity value of the cleaning solution, a concentration value of the cleaning solution, a temperature of the cleaning solution, a workpiece surface condition, a number of processed workpieces 111 by the same cleaning solution, a remaining use time of the filter 172, an indicator of pipeline cleanliness, a performance indicator of the FFU 120, a performance indicator of the exhaust unit 130, and a processing type and a process recipe of a process immediately prior the wet cleaning operation.

As discussed previously, according to some embodiments, the viscous property of the cleaning solution comes from the contaminants dissolved in the cleaning solution during previous wet cleaning operations and tends to increase along with the number of recycles for which the same cleaning solution have been used, and thus is also related to the current status of the cleaning solution. Further, the effect of the wet cleaning operation at least depends in part upon the reaction of the chemical elements with the defects on the workpiece 111. Thus, the concentration value of the cleaning solution tends to decrease along with the amount of defects being processed with the same cleaning solution due to consumption of the chemicals in the cleaning solution.

According to some embodiments, the temperature of the cleaning solution may influence the reaction speed and effect of the cleaning solution. The temperature information of the cleaning solution can be sensed through a sensor mounted on the first pipe 142 or the second pipe 144. Further, according to some embodiments, the surface property, e.g., a hydrophilic or hydrophobic surface of the material layer 204, would also affect the reaction efficiency of the cleaning solution. The index of hydrophilicity or hydrophobicity can be obtained from the lot information of the workpiece and accessed through the database 160. In the proposed prediction model, the input parameter P-C1 may include an indicator of a temperature of the cleaning solution or an index of hydrophilicity or hydrophobicity of the surface of the workpiece.

According to some embodiments, the contaminants removed and carried away by the cleaning solution are recycled through the pipeline network between the semiconductor processing tool 110 and the chemical container 140. A portion of the contaminants may stick to pipe walls of the pipeline due to their viscosity or adhesity, and therefore the performance of removing and filtering the contaminants may not be fully covered by the filter 172. To improve the efficiency of contaminant removal from the cleaning solution, the equipment engineer will perform a pipeline cleaning operation for cleaning the pipe walls of the pipeline network on a regular basis. In the proposed prediction model, the input parameter P-C1 may further include an indicator of pipeline cleanliness, which is closely related to the period of time, e.g., represented by a number of days or hours, away from the date and time when the pipe wall was cleaned.

According to some embodiments, a source of the contaminants is the particles flowing in the air in the semiconductor processing system 10. The air quality in the semiconductor processing system 10 may be well managed through controlling the FFU 120 and the exhaust unit 130, e.g., the rotational speed of the fan or air flow rate of the FFU 120, or the exhaust unit 130, or an exhaust pressure of the exhaust unit 130. Thus, in the proposed prediction model, the input parameter P-C1 may further include an indicator of air quality in the semiconductor processing system 10, which is closely related to the air flow rate of the fan of the FFU 120 or the exhaust unit 130, or the exhaust pressure of the exhaust unit 130.

According to some embodiments, another source of the contaminants is the residue of a layer left on the material layer 204 during an operation before the wet cleaning operation. The property of the residue, e.g., its material and amount, may be closely related to the process type and the process recipe of the previous operation. For example, if an etching process is performed prior to the wet cleaning operation, the performance of the wet cleaning operation is closely related to the etching type, the etch recipe, and the etched material of the etching operation. Thus, in the proposed prediction model, the training input parameters P-C1 may also include the process type and process recipe of a process immediately prior to the wet cleaning operation.

According to some embodiments, the training input parameters P-C2 in the second category C2 may reflect the history of the cleaning solution. The history of the cleaning solution may also be referred to herein as a wafer loading of the current cleaning operation. The history of the cleaning solution may be mainly related to the recycling of the cleaning solution, which results in the quality degradation of the cleaning solution. The training input parameters P-C2 may at least include one or more of the viscosity value of the cleaning solution, the concentration value of the chemicals or water in the cleaning solution, the number of processed workpieces 111 and the indicator of pipeline cleanliness.

According to some embodiments, the training input parameters P-C3 in the third category C3 may reflect the environmental factor of the cleaning operation. The environmental factor of the cleaning operation may be mainly related to the management of the facility and equipment with which the cleaning operation is performed. The training input parameters P-C3 may at least include one or more of the performance indicator of the FFU 120, the performance indicator of the exhaust unit 130, and an electrostatic charge value of the workpiece 111.

According to some embodiments, during the wet cleaning operation, the cleaning solution is dispensed onto the workpiece 111 while the workpiece 111 is being spun by the spin base. The friction between the cleaning solution and other substances, such as the material layer 204 or air, may cause generation of electrostatic charges on the surface of the cleaning solution. The electrostatic force would attract some particles in the cleaning solution to come out of the cleaning solution and stick to the surface of the workpiece 111. The level of the electrostatic charges may be closely related to some specific properties of the workpiece 111 and/or the cleaning solution, and may be measured in an off-line experiment. The data of the electrostatic charge values can be accessed via a look-up table and obtained through the database 160. Thus, in the proposed prediction model, the training input parameter P-C3 may further include an electrostatic charge value.

According to some embodiments, the training input parameters P-C4 in the fourth category C4 may reflect other factors not directly resulting from the cleaning solution and the semiconductor processing system 10. The training input parameters P-C4 at least include the process factor and the lot information of the workpiece 111. The process factor of the workpiece 111 may relate generally to the materials, process types and process recipes of the processes for manufacturing the workpiece 111, including those of the process immediate prior to the wet cleaning operation. Further, the lot information of the workpiece 111 relates generally to the circuit layout of the workpiece, such as the number or size of dies (gross die) of the workpiece 111, the circuit density of the dies on the workpiece 111, the technology (e.g., the application type, the circuit type, the semiconductor manufacturing node, etc.) used for the dies of the workpiece 111, and the constitution of material layers in the workpiece 111.

According to some embodiments, the training input parameters P-C5 in the fifth category C5 may be related to the performance factor of the cleaning operation. The performance of the cleaning operation may be determined via the image 302 after the cleaning operation. The image 302 for the material layer 204 may be related to the number of defects, the defect types of these detected defects, and the distribution type (e.g., a cluster type, a local zone type, a scratch type, etc.) of the defects. According to some embodiments, the training input parameters P-C5 are omitted from the training input parameters TP of the input stage 410.

FIG. 4B shows a schematic diagram of a prediction phase of the cleaning configuration prediction framework 400, in accordance with some embodiments of the present disclosure. The prediction phase is similar to the training phase in that they share the same structure of the prediction model 420. The difference between the prediction phase and the training phase is that the training input parameters TP, e.g., P-C1, P-C2, P-C3, P-C4 and P-C5, of the input stage 410 are replaced with their counterpart real-time input parameters RP, e.g., RP-C1, RP-C2, RP-C3, RP-C4 and RP-C5, wherein the real-time input parameters RP are sensed or accessed in real time from the sensors or the database 160 of the semiconductor processing system 10 for the target wet cleaning operation that is to be performed. Further, the model parameters of the prediction model 420 in the prediction phase have been considered to be converged after the training phase is completed and would be kept unchanged during the prediction phase. Further, the error function stage 440 and the feedback loop are removed from FIG. 4B since they are not necessary in the prediction phase. The predicted outcome of the output stage 430 can provide a reliable real-time predicted outcome based on the real-time input parameters RP.

According to some embodiments, the real-time input parameters RP and the inspection result of the defect inspection operation, e.g., the image of the defect inspection operation, are further provided to the database 160 for data update. The prediction model 420 can be further trained using the updated data as updated or new pieces of training data from the real-time input parameters RP and the inspection result of the defect inspection operation and thus the model parameters of the prediction model 420 can be fine-tuned continually.

FIG. 4C shows a schematic diagram of a training phase of a cleaning configuration prediction framework 402, in accordance with some embodiments of the present disclosure. The cleaning configuration prediction framework 402 is similar to the cleaning configuration prediction framework 400 in many aspects, and descriptions of these features are not repeated for brevity. The cleaning configuration prediction framework 402 is different from the cleaning configuration prediction framework 400 in that the cleaning configuration prediction framework 402 includes an output stage 430 having multiple outcomes, e.g., an outcome #1, an outcome #2,…an outcome #N, where N is an integer greater than one. Each of the multiple outcomes of the output stage 430 may correspond to an adjustment of a parameter in the cleaning configuration. According to some embodiments, the parameters corresponding to the multiple outcomes include a decision of whether the cleaning solution is to be replaced with a new cleaning solution, an adjustment (increase or decrease) of the cleaning period of the cleaning operation, an adjustment (increase or decrease) of a flow rate of the cleaning solution, an adjustment (increase or decrease) of the number of cleaning rounds of the cleaning operation, an adjustment (increase or decrease) of a spinning rate of the spin base, an adjustment (increase or decrease) of the air flow rate of the FFU 120 or the exhaust unit 130, and an adjustment (increase or decrease) of the exhaust pressure of the exhaust unit 130.

FIG. 4D shows a schematic diagram of a prediction phase of the cleaning configuration prediction framework 402, in accordance with some embodiments of the present disclosure. The working principle of the prediction phase of the cleaning configuration prediction framework 402 is similar to that of the cleaning configuration prediction framework 400, except that the output stage 430 of the cleaning configuration prediction framework 402 is configured to provide multiple outcomes.

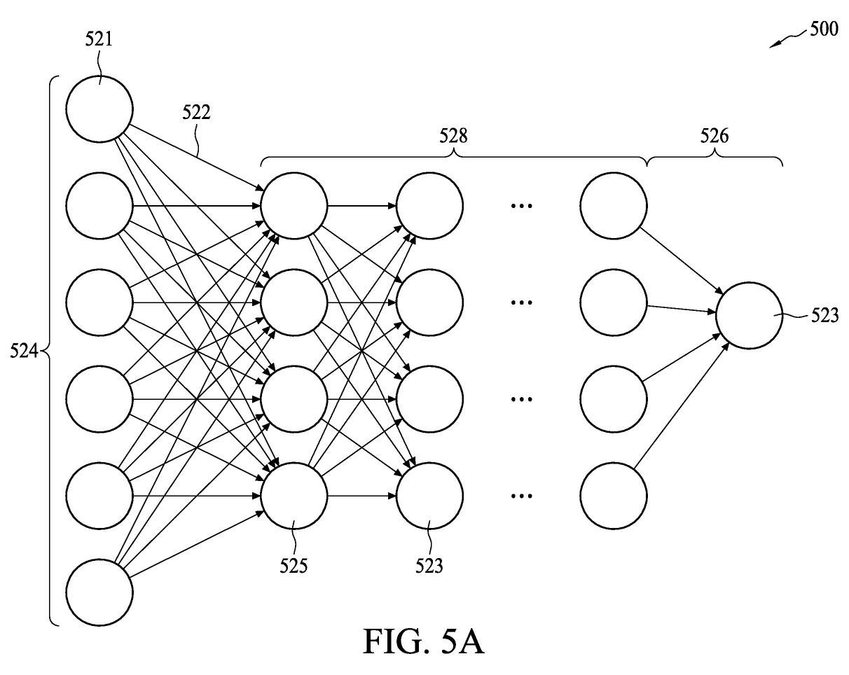

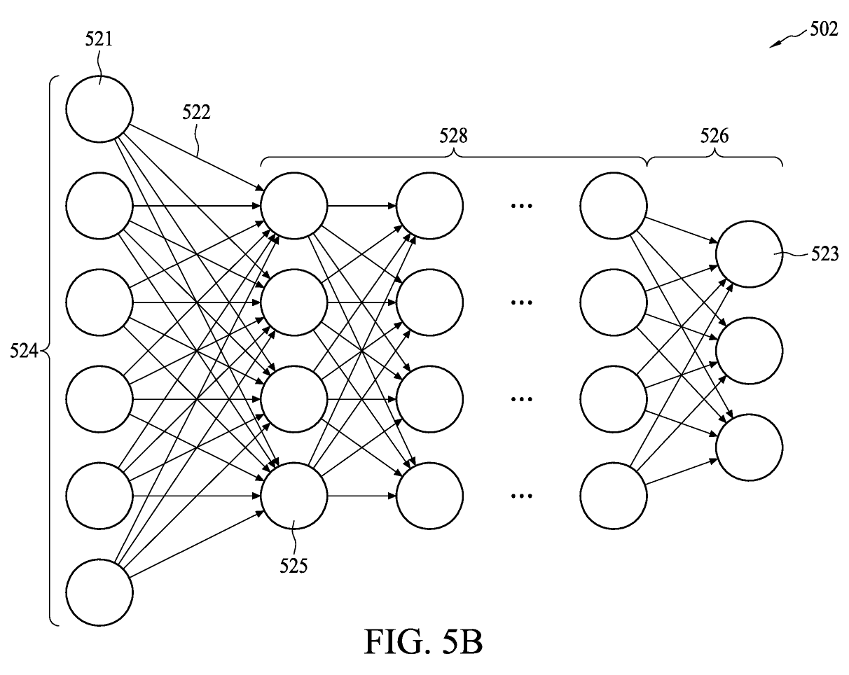

The prediction model 420 can be implemented by various kinds of computing architectures widely adopted in the field of artificial intelligence, deep learning, machine learning or the like. Some example artificial intelligence models that can be applied to the prediction model 420 include neural networks, decision trees, linear regression, logistic regression, naïve Bayes, random forest, or other suitable models. In the present disclosure, a neural network is used as an example to explain the prediction model 420, although other types of models are also within the contemplated scope of the present disclosure. FIG. 5A shows a schematic diagram of a neural network 500, in accordance with some embodiments of the present disclosure. The neural network model 500 has an architecture of a multi-layer perceptron, that is constructed by a group of neurons (nodes) 52 interconnected through connections 522 with respective weights. The group of nodes may form various layers, e.g., an input layer 524 comprised of input nodes 521, an output layer 526 comprised of an output node 523 and one or more hidden layers 528 each comprised of a plurality of hidden nodes 525. Model parameters of the neural network 500 may be determined, such as the number of nodes 521 in each of the input layer 524, the output layer 526 and the hidden layers 528, and the interconnection topology of the connections 522. According to some embodiments, the output layer 526 may include one output node 523. In the present embodiment, referring to FIGS. 4A, 5A and 5B, during the training phase, each node 521 of the input layer 524 corresponds to one of the training input parameters TP of the input stage 410, and the output layer 430 corresponds to the predicted outcome of the output stage 430. An iterative training procedure for the weights of the connections 522 is performed until the values of the weights attain converged values. The values of the weights are regarded as attaining convergence in terms of the training error of the error function stage 440, in which these converged values of the weights reach a minimal convergence error. During the training phase, the nodes 521 of the input layer 524 are fed with the real-time input parameters RP, and the node 523 of the output layer 526 in the neural network 500 is configured to generate the predicted outcome of the output stage 430.

FIG. 5B shows a schematic diagram of a neural network 502, in accordance with some embodiments of the present disclosure. The neural network 502 is similar to the neural network 500 in the input layer 524 and the hidden layers 528, and descriptions of these similar features are not repeated for brevity. The neural network 502 includes an output layer 526 comprised of multiple nodes 523, which correspond to multiple predicted outcomes of the output stage 430 shown in FIGS. 4C and 4D.

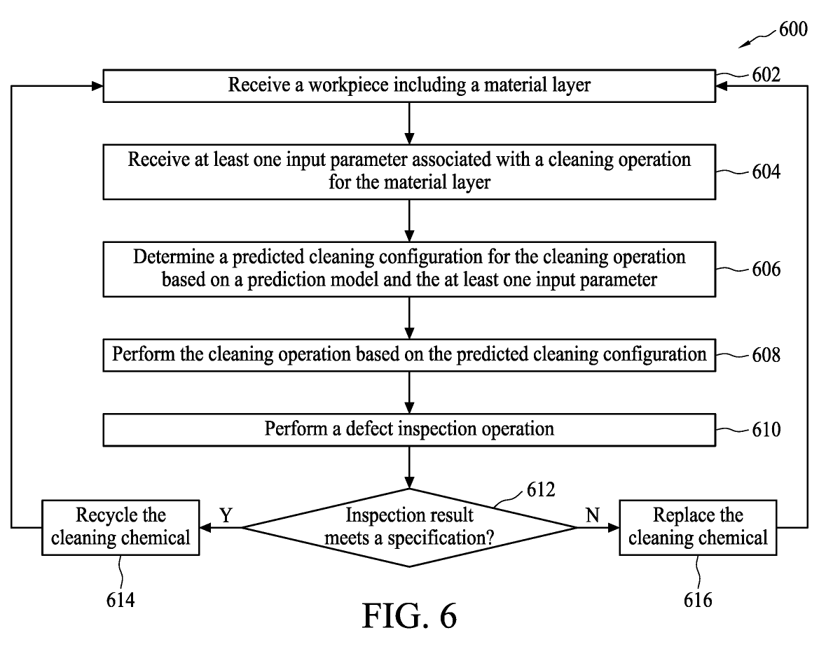

FIG. 6 shows a flowchart of a wet cleaning method 600, in accordance with some embodiments of the present disclosure. It shall be understood that additional steps can be provided before, during, and after the steps in method 600, and some of the steps described below can be replaced with other embodiments or eliminated. The order of the steps shown in FIG. 6 may be interchangeable. Some of the steps may be performed concurrently or independently.

At step 602, a workpiece including a material layer is received. At step 604, at least one input parameter associated with a cleaning operation for the material layer is received or provided. According to some embodiments, steps 602 and 604 can be interchanged or performed at the same time. Before step 602 or 604, a process, e.g., an etching operation, is performed prior to the wet cleaning operation.

At step 606, a predicted cleaning configuration is determined based on a prediction model and the at least one parameter. According to some embodiments, the determining of the predicted cleaning configuration includes changing a configuration of the cleaning operation for a current cleaning operation from a previous cleaning configuration based on an update to the at least one first parameter, in response to determining that no defect is detected on the material layer in a previous cleaning operation. This real-time adaptation of the cleaning configuration adaptation to the dynamic variations of the cleaning condition for the current cleaning operation may provide better configuration matching to each round of cleaning operations and save more times of unnecessary replacement of the cleaning solution.

According to some embodiments, the determining of the cleaning configuration includes only a decision of reusing or replacing the cleaning solution with all other at least one input parameter of the cleaning configuration unchanged.

According to some embodiments, the determining of the cleaning configuration includes replacing the cleaning solution even in response to determining that no defect is detected on the material layer in a previous cleaning operation. This is because the prediction model has the capability of predicting a use limit of the cleaning solution before it generates an unsuccessful cleaning operation.

According to some embodiments, the determining of the cleaning configuration includes only a decision of reusing or replacing the cleaning solution, with all other at least one input parameter of the cleaning configuration unchanged.

At step 608, the cleaning operation is performed based on the predicted cleaning configuration. At step 610, a defect inspection operation is performed on the material layer to determine whether any defect is detected.

At step 612, it is determine whether the inspection result meets a specification. According to some embodiments, the number of defects and their defect types are examined through the defect inspection operation. The inspection result is further examined to determine whether the inspection result meets the specification.

If the inspection result meets the specification, it is determined at step 614 that the cleaning solution be recycled and reused in the next cleaning operation, and method 600 loops back to step 602, in which another workpiece is received and followed by the subsequent steps. However, if the inspection result fails to meet the specification, it is determined at step 614 that the cleaning solution be replaced with a new cleaning solution. The method 600 then loops back to step 602, in which another workpiece is received and followed by the subsequent steps.

In accordance with some embodiments of the present disclosure, a method includes receiving a workpiece including a material layer; receiving at least one input parameter associated with a cleaning operation for the material layer; determining a predicted cleaning configuration for the cleaning operation based on a prediction model and the at least one input parameter; performing the cleaning operation based on the predicted cleaning configuration; and performing a defect inspection operation on the material layer.

In accordance with some embodiments of the present disclosure, a method includes providing a prediction model for a cleaning operation; and performing a loop of: receiving a workpiece including a material layer formed thereon; determining a cleaning configuration associated with the cleaning operation for the material layer based on the prediction model; performing the cleaning operation on the material layer based on the cleaning configuration; and determining whether a defect exists on the material layer.

In accordance with some embodiments of the present disclosure, a semiconductor processing system includes a processing tool configured to support a workpiece; a pipeline network connected to the processing tool and configured to circulate a cleaning solution between a container and the processing tool; at least one sensor configured to sense at least one parameter associated with a cleaning operation for the workpiece; and an analyzer configured to: execute a prediction model for determining a cleaning configuration associated with the cleaning operation for a material layer based on the at least one parameter; performing the cleaning operation with the cleaning configuration; and determining whether a defect exists on the material layer.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece including a material layer;
receiving at least one input parameter associated with a cleaning operation for the material layer;
determining a predicted cleaning configuration for the cleaning operation based on a prediction model and the at least one input parameter;
performing the cleaning operation based on the predicted cleaning configuration; and
performing a defect inspection operation on the material layer.

2. The method of claim 1, wherein the performing of the cleaning operation comprises dispensing a cleaning solution onto the material layer and recycling the cleaning solution.

3. The method of claim 2, comprising replacing the cleaning solution with a new cleaning solution based on an inspection result of the defect inspection operation indicating that a specification is been met.

4. The method of claim 2, comprising recycling the cleaning solution for use by another cleaning operation based on an inspection result of the defect inspection operation indicating that a specification is met.

5. The method of claim 1, wherein the at least one input parameter set comprises at least one of the following: a viscosity value of a cleaning solution, a concentration value of a chemical of the cleaning solution, a temperature of the cleaning solution, an index of hydrophilicity or hydrophobicity of an surface of the workpiece, a number of processed workpieces by the cleaning solution, or an electrostatic charge value on the workpiece.

6. The method of claim 1, wherein the at least one input parameter set comprises at least one of the following: a remaining use time of a filter for filtering a cleaning solution, an index of cleanliness of a pipeline for transporting the cleaning solution, and lot information for the workpiece.

7. The method of claim 1, further comprising training the prediction model with historic data of the at least one input parameter, wherein the at least one input parameter comprises images of the material layer by the defect inspection operation.

8. The method of claim 7, further comprising providing an inspection result of the defect inspection operation as updated training data to the prediction model and updating the prediction model by training the prediction model using the updated training data.

9. The method of claim 1, wherein the prediction model is configured to generate multiple predicted outcomes based on the at least one input parameter.

10. The method of claim 9, wherein one of the multiple predicted outcomes comprises one of the following: an adjustment of a flow rate of a cleaning solution, an adjustment of a cleaning period of the cleaning operation, an adjustment of a number of cleaning rounds, or replacing the cleaning solution with a new cleaning solution.

11. A method, comprising:
providing a prediction model for a cleaning operation; and
performing a loop of:
receiving a workpiece including a material layer formed thereon;
determining a cleaning configuration associated with the cleaning operation for the material layer based on the prediction model;
performing the cleaning operation on the material layer based on the cleaning configuration; and
determining whether a defect exists on the material layer.

12. The method of claim 11, wherein the determining of whether a defect exists on the material layer comprises providing an inspection result including a defect count and a defect type of respective defects on the material layer.

13. The method of claim 12, wherein the determining of the cleaning configuration comprises changing a configuration of the cleaning operation for a current cleaning operation based on an update to at least one first parameter to the prediction model in response to determining that no defect is detected on the material layer in a previous cleaning operation.

14. The method of claim 11, wherein the determining of the cleaning configuration comprises replacing a cleaning solution of the cleaning operation in response to determining that no defect is detected on the material layer in a previous cleaning operation.

15. The method of claim 11, wherein determining of the cleaning configuration comprises only a decision of reusing or replacing a cleaning solution of the cleaning operation with all other at least one input parameter of the cleaning configuration unchanged.

16. The method of claim 11, wherein the prediction model comprises an artificial neural network formed of an input layer, an output layer, at least one hidden layer and a plurality of connections connecting nodes of the input layer, the output layer and the at least one hidden layer with corresponding weights, further comprising, during a training phase, providing historic data of input parameters of the prediction model as training data to be fed into the input layer.

17. The method of claim 16, further comprising, during the training phase, providing at least one actual outcome to be compared with at least one predicted outcome of the prediction model.

18. A semiconductor processing system, comprising:
a processing tool configured to support a workpiece;
a pipeline network connected to the processing tool and configured to circulate a cleaning solution between a container and the processing tool;
at least one sensor configured to sense at least one parameter associated with a cleaning operation for the workpiece; and
an analyzer configured to:
execute a prediction model for determining a cleaning configuration associated with the cleaning operation for a material layer based on the at least one parameter;
performing the cleaning operation with the cleaning configuration; and
determining whether a defect exists on the material layer.

19. The semiconductor processing system of claim 18, wherein the at least one parameter comprises at least one of the following: a viscosity value of the cleaning solution, a concentration value of the cleaning solution, a temperature of the cleaning solution, a circuit type of the workpiece, a size of dies on the workpiece, an index of hydrophilicity or hydrophobicity of an surface of the workpiece, a number of processed workpieces by the cleaning solution, an electrostatic charge value on the workpiece, a remaining use time of a filter for filtering the cleaning solution, a time away from a pipeline cleaning operation, a flow rate of a fan filter unit, or an exhaust pressure of an exhaust unit.

20. The semiconductor processing system of claim 18, wherein the analyzer is further configured to, in response to a defect being detected, update the prediction model for the cleaning operation with information of the defect.
